(19) United States
(12) Patent Application Publication
(10) Pub. No.: US 2026/0362751 A1
(43) Pub. Date: Nov. 12, 2026

(54) DEVICE, SYSTEM AND METHOD FOR OPTIMIZING CHARACTERISTICS OF A TRANSISTOR CHANNEL

(71) Applicant: Versum Materials US, LLC, Tempe, AZ (US)

(72) Inventor: Foroozan Sarah Koushan, San Jose, CA (US)

(21) Appl. No.: 19/485,543

(22) PCT Filed: May 16, 2024
(86) PCT No.: PCT/US2024/029584

§ 371 Date: Nov. 18, 2025

Related U.S. Application Data
(60) Provisional application No. 63/503,217, filed on May 19, 2023.

(51) Int. Cl. H10D 30/67; H10D 30/01; H10D 30/69; H10D 62/17; H10D 64/01; H10D 64/68

(52) U.S. Cl. CPC H10D 30/6757; H10D 30/0314; H10D 30/0415; H10D 30/6731; H10D 30/6736; H10D 30/6739; H10D 30/701; H10D 62/235; H10D 64/033; H10D 64/689

(57) ABSTRACT

A device and related method are disclosed. The device may include a gate structure, a first electrode, and a second electrode. In addition, the device may include a multilayered channel structure configured to be in electrical communication with the first electrode and the second electrode. The multilayered channel structure has a carrier deficient layer and an electron injection layer disposed on the carrier deficient layer.

### BACKGROUND

### Relevant Field

The present disclosure relates to semiconductors. More particularly, the present disclosure relates to a device, system, and method for optimizing characteristics of a transistor channel, e.g., such as a FeFET's channel.

### Description of Related Art

Electron mobility is an import parameter in the design, manufacturing, and use of semiconductor devices and materials and determines how electrons move within the material when an electric field is applied to the material. Electron mobility determines the electrical conductivity and performance of various electronic devices, including transistors, diodes, and integrated circuits generally. Higher electron mobility enables for fasting switching times allowing the device to operate more efficiently and at high frequencies.

In semiconductor devices, current is primarily determined by the flow of electrons and holes, which are the primary charge carriers. These charge carries move through a material and therefor define the amount of current moving through the material in response to an electric field acting on them.

Electron mobility can be determined by various factors, such as material properties, temperature, doping, and scattering mechanism. Understanding the behavior of a semiconductor device therefor depends upon the characterization of the electron mobility of the semiconductor materials used in the semiconductor device.

If the electron mobility is unstable, it can lead to inconsistent device performance and might cause the device to fail prematurely. In applications where device are subject to a wide range of operating conditions, having stable electron mobility allows the device's performance to remain consistent. Unstable electron mobility could potentially lead to device malfunction and degraded performance either throughout all its operating range or in certain ranges within its operating range, thereby reducing its dynamic range.

Amorphous metal-oxide semiconductor materials have been used in semiconductors devices before, such as in thin-film transistors, but have not been widely adopted because of challenges associated with its electron mobility stability. Those challenges include balancing high electron mobility with a device's threshold-voltage stability within the channel of a TFT devices.

### SUMMARY

In one general aspect, a semiconductor device may include a gate structure. The semiconductor device may also include a first electrode and a second electrode. The semiconductor device may in addition include a multilayered channel structure configured to be electrically coupled to the first electrode and the second electrode. The multilayered channel structure has a carrier deficient layer and an electron injection layer disposed on the carrier deficient layer.

Additional, optional, and/or alternative aspects are described in the following. The semiconductor device may include a dielectric layer disposed between the gate structure and the multilayered channel structure. The dielectric layer may be formed from a ferroelectric material. The multilayered channel may include a plurality of carrier deficient layers including the carrier deficient layer and a plurality of electron injection layers including the electron injection layer, wherein the plurality of carrier deficient layers and the plurality of electron injection layers are interleaved together to thereby form an interleaved multilayered channel structure.

The semiconductor device may include a ferroelectric layer disposed between the gate structure and the interleaved multilayered channel structure. The semiconductor device may include an insulator. The multilayered channel structure can be disposed on the insulator. The first side insulator may be disposed on a first side of the multilayered channel structure. The second side insulator may be disposed on a second side of the multilayered channel structure. The first side insulator may be in contact with the insulator and the second side insulator may be in contact with the insulator.

The gate structure may be disposed on the insulator. The gate structure can form a trapezoidal cross-sectional shape. The dielectric layer may be disposed on the gate structure and the insulator. The multilayered channel structure may be disposed on the dielectric layer. The first electrode and the second electrode may be in electrical communication with each other through the multilayered channel structure.

The multilayered channel structure may be disposed on the insulator. The dielectric layer may be disposed on the multilayered channel structure. The gate structure may be disposed on the dielectric layer The dielectric layer may be made of a ferroelectric material. The first electrode may be in electrical communication with the multilayered channel structure. The first electrode may be in physical contact with the multilayered channel structure. The first electrode may be in physical contact with the dielectric layer. The first electrode may be in physical contact with the insulator. The semiconductor device may include another insulator disposed adjacent to the first electrode at an opposite side to the multilayered channel structure. The semiconductor device may include a metal where the gate structure is disposed on the metal. The semiconductor device may include a dielectric layer disposed on the gate structure. The first electrode is disposed on the multilayered channel structure and the dielectric layer and the second electrode is disposed on the multilayered channel structure and the dielectric layer.

The semiconductor device may include an interposed insulator disposed between the first electrode and the second electrode. The multilayered channel structure may be disposed on the dielectric layer. The semiconductor device may include a ferroelectric material disposed on the gate structure. The multilayered channel structure may be disposed on the ferroelectric material. The semiconductor device may include a first insulator disposed adjacent to the gate structure on a first side and a second insulator disposed adjacent to the gate structure on a second side. The first electrode may be a source structure. The second electrode may be a drain structure.

The carrier deficient layer may be an indium(III) oxide layer with an added dopant with a high bond-dissociation energy. The added dopant may be selected from the group consisting of tungsten(VI) oxide, silicon dioxide, and antimony tetroxide. The electron injection layer may be pure indium(III) oxide. The electron injection layer may be indium(III) oxide annealed in air. The electron injection layer may be indium(III) oxide annealed with an added dopant with a low bond-dissociation energy.

The added dopant may be a titanium dioxide. The device is a thin-film transistor. The device may be disposed on a back-end of a line portion of an integrated circuit. The device may be disposed on a front-end of a line portion of an integrated circuit. The multilayered channel structure may be less than 10 nanometers in thickness. The carrier deficient layer may have a first thickness and the electron injection layer may have a second thickness where a ratio between the first thickness and the second thickness is predetermined.

In yet additional aspects, an integrated circuit system may include at least one integrated circuit having a plurality of devices as described here.

In another aspect of the present disclosure, a method of making an integrated circuit is described and includes forming a gate structure; forming a first electrode; forming a second electrode; forming a multilayered channel structure disposed between the first electrode and the second electrode; forming a carrier deficient layer of the multilayered channel structure; and forming an electron injection layer disposed in contact with the carrier deficient layer.

The carrier deficient layer may be an indium(III) oxide layer, wherein the method further comprises adding a dopant with a high bond-dissociation energy to the indium(III) oxide layer. The dopant may be selected from the group consisting of tungsten(VI) oxide, silicon dioxide, and antimony tetroxide. The electron injection layer may be pure indium(III) oxide. The electron injection layer is indium(III) oxide. The method further comprises annealing the electron injection layer in air.

The electron injection layer may be indium(III) oxide and the method may further include the act of annealing the electron injection layer with an added dopant with a low bond-dissociation energy. The added dopant may be a titanium dioxide. The method may form a thin-film transistor. A dielectric layer may be disposed between the gate structure and the multilayered channel structure.

The method may include forming the dielectric layer from a ferroelectric material. Each forming act may be performed on a back-end of a line portion of an integrated circuit. The method may form less than 10 nanometers of thickness of the multilayered channel structure. The carrier deficient layer may have a first thickness and the electron injection layer may have a second thickness. The method may further comprise forming a ratio between the first thickness and the second thickness is predetermined.

The method may include forming a plurality of carrier deficient layers including the carrier deficient layer; forming a plurality of electron injection layers including the electron injection layer; and interleaving the plurality of carrier deficient layers and the plurality of electron injection layers thereby forming an interleaved multilayered channel structure. A ferroelectric layer may be disposed between the gate structure and the interleaved multilayered channel structure.

The method may further include forming an insulator; forming the gate structure on the insulator; forming a trapezoidal cross-sectional shape of the gate structure; forming a dielectric layer on the gate structure and the insulator; forming the multilayered channel structure on the dielectric layer; and/or communicating electrically communicating between the first electrode and the second electrode through the multilayered channel structure. The multilayered channel structure may be disposed the insulator.

The method may include one or more acts of: forming the dielectric layer on the insulator; forming the gate structure on the insulator; forming the dielectric layer from a ferroelectric material; and/or electrically communicating the first electrode with the multilayered channel structure.

The first electrode may be in physical contact with the multilayered channel structure. The first electrode may be in physical contact with the dielectric layer.

### BRIEF DESCRIPTION OF THE DRAWINGS

These and other aspects will become more apparent from the following detailed description of the various embodiments of the present disclosure with reference to the drawings wherein:

FIG. 1 shows a cross-sectional view of a thin-film transistor having a channel with a carrier deficient layer and an electron injection layer in accordance with an embodiment of the present disclosure;

FIG. 2 shows a cross-sectional view of a thin-film transistor having a channel with a carrier deficient layer and an electron injection layer in accordance with an embodiment of the present disclosure;

FIG. 3 shows a cross-sectional view of a ferroelectric field-effect transistor having a channel with a carrier deficient layer and an electron injection layer in accordance with an embodiment of the present disclosure;

FIG. 4 shows a cross-sectional view of a ferroelectric field-effect transistor having a channel with a carrier deficient layer and an electron injection layer in accordance with an embodiment of the present disclosure;

FIG. 5 shows a cross-sectional view of a thin-film transistor disposed on a metal having a channel with a carrier deficient layer and an electron injection layer in accordance with an embodiment of the present disclosure;

FIG. 6 shows a cross-sectional view of a thin-film transistor disposed on an insulator having a channel with a carrier deficient layer and an electron injection layer in accordance with an embodiment of the present disclosure;

FIG. 7 shows a cross-sectional view of a ferroelectric field-effect transistor disposed on a metal having a channel with a carrier deficient layer and an electron injection layer in accordance with an embodiment of the present disclosure;

FIG. 8 shows a cross-sectional view of a ferroelectric field-effect transistor disposed on an insulator having a channel with a carrier deficient layer and an electron injection layer in accordance with an embodiment of the present disclosure;

FIG. 9 shows a cross-sectional view of a thin-film transistor having a channel with interleaved carrier deficient layers and electron injection layers in accordance with an embodiment of the present disclosure;

FIG. 10 shows a cross-sectional view of a ferroelectric field-effect transistor having a channel with interleaved carrier deficient layers and electron injection layers in accordance with an embodiment of the present disclosure;

FIG. 11 shows a cross-sectional view of a thin-film transistor having a channel with interleaved carrier deficient layers and electron injection layers in accordance with an embodiment of the present disclosure;

FIG. 12 shows a cross-sectional view of a ferroelectric field-effect transistor having a channel with interleaved carrier deficient layers and electron injection layers in accordance with an embodiment of the present disclosure;

FIG. 13 shows a graphic illustrating prophetic results expected from having a channel layer with various types of materials in accordance with an embodiment of the present disclosure; and

FIG. 14 shows a flow chart diagram of a method of forming a semiconductor device, such as a transistor, in accordance with an embodiment of the present disclosure.

### DETAILED DESCRIPTION

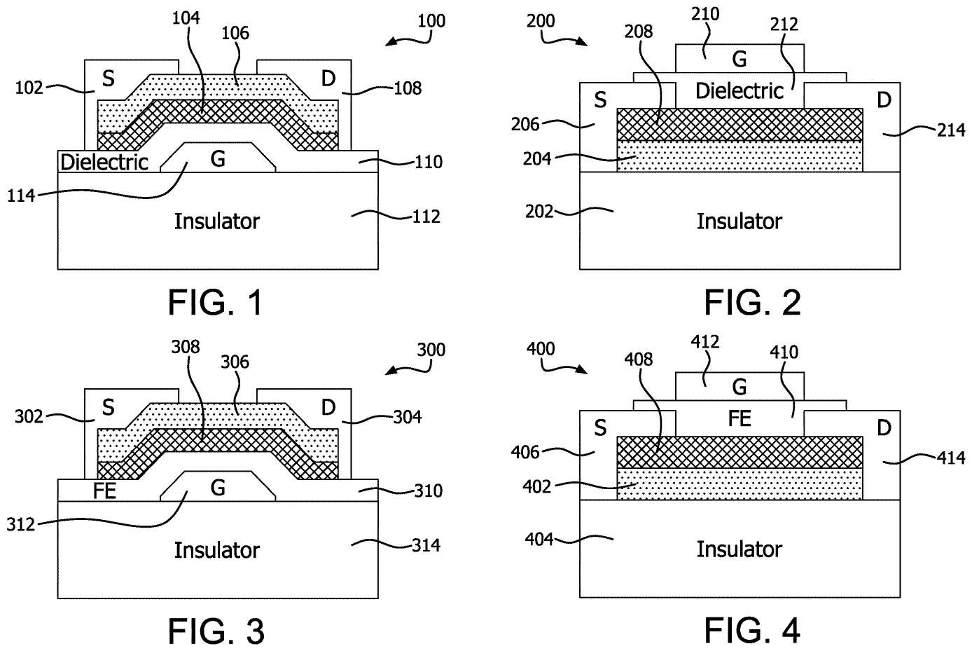

FIG. 1 shows a cross-sectional view of a thin-film transistor 100 having a channel with a carrier deficient layer 104 and an electron injection layer 106 in accordance with an embodiment of the present disclosure. The gate 114 in transistor 100 may be constructed first in the transistor 100 making it what was is commonly known as a Back-Gate transistor or gate-first FET to one of ordinary skill in the relevant art. The transistor 100 may have a trapezoidal cross-section shape for a gate 114 in some specific embodiments as is shown in FIG. 1 (however, other shapes, designs, and configurations may be used and are known to one of ordinary skill in the relevant art). The transistor 100 may be a thin-film transistor and may be disposed on the BEOL (“Back-end-of-the-line”) or on the FEOL (“Front-end-of-the-line”), some in specific embodiments.

The transistor 100 includes an insulator 112 with a gate structure 114, a type of electrode, disposed thereon. The transistor 100 also includes a dielectric layer 110 disposed on the gate structure 114 and the insulator 114. The dielectric layer 110 prevents substantial direct current flow between the gate structure 114 and the source structure 102 and/or between the gate structure 114 and the drain structure 108. A drain structure or source structure as disclosed herein may be formed with materials including, but not limited to, Pd, Mo, Al/Ti, W, Cu, TiN, Pt, etc. or some combination thereof. A gate structure as disclosed herein may be formed with materials including, but not limited to W, Cu, Al, TiN, etc. or some combination thereof. Disposed between the dielectric and the source structure 102 and the drain structure 108 is a channel structure comprising the carrier deficient layer 104 and the electron injection layer 106. The total thickness of the channel structure including the carrier deficient layer 104 and the electron injection layer 106 may be less than 10nanometers in thickness, in some specific embodiments. In yet additional embodiments, the ratio of the thicknesses of the carrier deficient layer 104 and the electron injection layer 106 may be a parameter determined during design and manufacturing that is adjusted to achieve target operating characteristics.

The carrier deficient layer 104 may be an indium(III) oxide layer with an added dopant with a high bond-dissociation energy. The added dopant may be selected from the group consisting of tungsten(VI) oxide, silicon dioxide, and antimony tetroxide. The electron injection layer 106 may be a pure indium(III) oxide, an indium oxide layer doped with a dopant with very low oxygen bond dissociation energy, etc. The electron injection layer 106 may be annealed in air and may have an added dopant with a low bond-dissociation energy. The added dopant may be titanium dioxide.

The In2O3 based oxide results in high electron mobility in the channel, which facilitates high drive current. The addition of a dopant with high bond-dissociation energy in the system may improve channel electrical stability as well as its process margin window against anneal time and oxygen flow during channel deposition. With trading off the high electronic mobility thus a channel material having two layers with one layer with high carrier injection capability improves current drive in the device. Total thickness of channel may remain <10 nm, but optimum characteristics may be achieved by modulating the thickness ratio of different layers in the channel.

FIG. 2 shows a cross-sectional view of a thin-film transistor 200 having a channel with a carrier deficient layer 208 and an electron injection layer 204 in accordance with an embodiment of the present disclosure. The transistor 200 has a gate structure 210 disposed on top of the transistor 200 as the last step of the manufacturing process thereby forming a top-gate FET device archecture. The transistor 200 may be a thin-film transistor and may be disposed on the BEOL or on the FEOL, in specific embodiments.

The transistor includes the insulator 202 with the electron injection layer 204 disposed thereon. The source structure 206 and the drain structure 214 are also partially disposed on the insulator 202. The carrier deficient layer 208 is disposed on the electron injection layer 204. The carrier deficient layer 208 and the electron injection layer 204 form the channel of the transistor 200. The dielectric 212 is disposed on the carrier deficient layer 208 and partially on the source structure 206 and the drain structure 214.

The total thickness of the channel structure including the carrier deficient layer 208 and the electron injection layer 204 may be less than 10 nanometers in thickness, in some specific embodiments. In yet additional embodiments, the ratio of the thicknesses of the carrier deficient layer 208 and the electron injection layer 204 may be a parameter determined during design and manufacturing that is adjusted to achieve target operating characteristics.

The carrier deficient layer 208 may be an indium(III) oxide layer with an added dopant with a high bond-dissociation energy. The added dopant may be selected from the group consisting of tungsten(VI) oxide, silicon dioxide, and antimony tetroxide. The electron injection layer 204 may be a pure indium(III) oxide or an indium oxide layer doped with a dopant with very low oxygen bond dissociation energy. The electron injection layer 204 may be annealed in air and may have an added dopant with a low bond-dissociation energy. The added dopant may be titanium dioxide. The Vgs voltage is above the Vth voltage, while the Vds is above zero, which is similar to most MOS transistors.

FIG. 3 shows a cross-sectional view of a ferroelectric field-effect transistor 300 having a channel with a carrier deficient layer 308 and an electron injection layer 306 in accordance with an embodiment of the present disclosure. The transistor 300 may be similar to the transistor 100 of FIG. 1, however, the transistor 300 includes a ferroelectric layer 310. The ferroelectric layers are described herein may be made of material including, but not limited to, one or more of lead zirconate titanate (PZT), hafnium zirconium oxide (HZO), barium titanate (BaTiO3), lead titanate (PbTiO3), and doped hafnium dioxide (HfO2). The doped HfO2 can include one or more of silicon doped HfO2, yttrium-doped HfO2, and aluminum-doped HfO2. The ferroelectric layer 310 can have its properties modified by application of an electric current to make the transistor 300 have a type of memory. The transistor 300 may a trapezoidal cross-section shape for the gate structure 312 as shown in FIG. 3, in some specific embodiments. The transistor 300 may be a thin-film transistor and may be disposed on the BEOL or on the FEOL, in specific embodiments.

The transistor 300 includes an insulator 314 with a gate structure 312 with a trapezoidal cross-sectional shape. The gate structure 314 is disposed on the insulator 314 in the specific embodiment shown in FIG. 3. A ferroelectric layer 310 of the transistor 300 is disposed on the gate structure 312 and the insulator 314. The ferroelectric layer 310 prevents substantial direct current flow between the gate structure 312 and the source structure 302 and/or between the gate structure 312 and the drain structure 304. The ferroelectric layer 310 can maintain an electric field polarization which affects the behavior of the transistor 300 and can be used to save a state or memory in the transistor 300.

Disposed between the ferroelectric layer 310 and the source structure 302 and the drain structure 304 is a channel structure comprising the carrier deficient layer 308 and the electron injection layer 306. The total thickness of the channel structure including the carrier deficient layer 308 and the electron injection layer 306 may be less than 10 nanometers in thickness, in some specific embodiments. In yet additional embodiments, the ratio of the thicknesses of the carrier deficient layer 308 and the electron injection layer 306 may be a parameter determined during design and manufacturing that is adjusted to achieve target operating characteristics.

The carrier deficient layer 308 may be an indium(III) oxide layer with an added dopant with a high bond-dissociation energy. The added dopant may be selected from the group consisting of tungsten(VI) oxide, silicon dioxide, and antimony tetroxide. The electron injection layer 306 may be a pure indium(III) oxide, an indium oxide layer doped with a dopant with very low oxygen bond dissociation energy, etc. The electron injection layer 306 may be annealed in air and may have an added dopant with a low bond-dissociation energy. The added dopant may be titanium dioxide.

FIG. 4 shows a cross-sectional view of a ferroelectric field-effect transistor 400 having a channel with a carrier deficient layer 408 and an electron injection layer 406 in accordance with an embodiment of the present disclosure. The transistor 400 may be a thin-film transistor and may be disposed on the BEOL or on the FEOL, in specific embodiments. The transistor 400 has a channel with a carrier deficient layer 408 and an electron injection layer 402. The transistor 400 also has a gate structure 412 disposed on an opposite side to the insulator 404.

The transistor 400 includes the insulator 404 with the electron injection layer 402 disposed thereon. The source structure 406 and the drain structure 414 are also partially disposed on the insulator 404. The carrier deficient layer 408 is disposed on the electron injection layer 402. The carrier deficient layer 408 and the electron injection layer 402 form the channel of the transistor 400. The ferroelectric material 410 is disposed on the carrier deficient layer 408 and partially on the source structure 406 and the drain structure 414.

The total thickness of the channel structure including the carrier deficient layer 408 and the electron injection layer 402 may be less than 10 nanometers in thickness, in some specific embodiments. In yet additional embodiments, the ratio of the thicknesses of the carrier deficient layer 408 and the electron injection layer 402 may be a parameter determined during design and manufacturing that is adjusted to achieve target operating characteristics.

The carrier deficient layer 408 may be an indium(III) oxide layer with an added dopant with a high bond-dissociation energy. The added dopant may be selected from the group consisting of tungsten(VI) oxide, silicon dioxide, and antimony tetroxide. The electron injection layer 402 may be a pure indium(III) oxide. The electron injection layer 402 may be annealed in air or in any other gas environment like N2 or O2 or some combination thereof, and may have an added dopant with a low bond-dissociation energy. The added dopant may be titanium dioxide.

To program the ferroelectric layer 410, the Vgs is set to be above the Vth, Vgs is set to be above 0 and the Vds=0 volts. The erase operation is performed when Vgs is less than 0 and Vds=0 volts. The read operation can occur with Vds=Vread and Vds=50 mV.

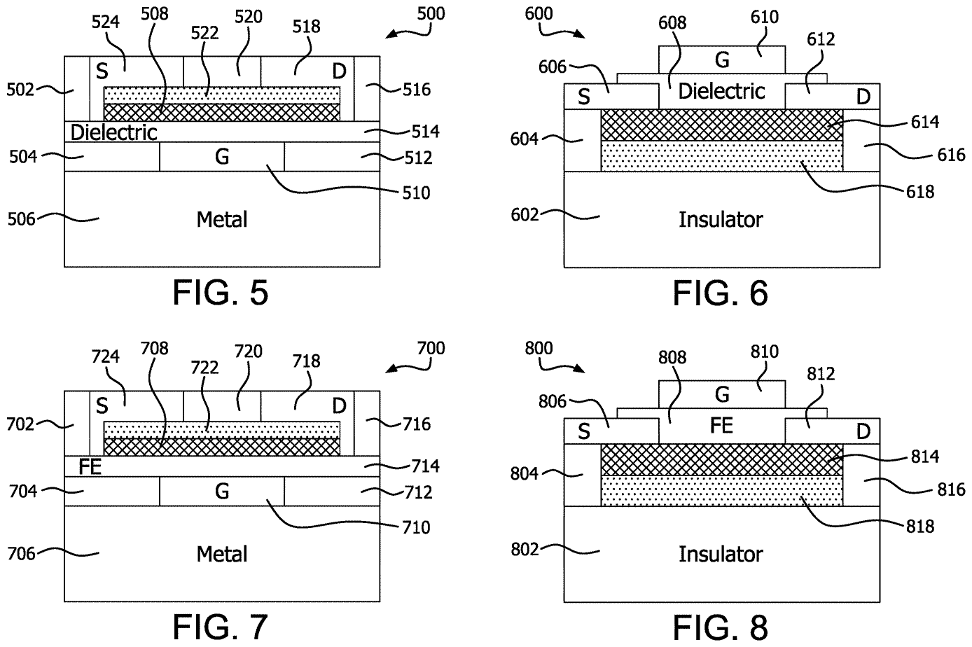

FIG. 5 shows a cross-sectional view of a thin-film transistor 500 disposed on a metal 506 having a channel with a carrier deficient layer 508 and an electron injection layer 522 in accordance with an embodiment of the present disclosure. A metal as disclosed herein may be any pure metal, any semi-pure metal, any combination of metals, any alloys, any elemental metals, any combination of elemental metals, material known as metal to one or ordinary skill in the relevant art, etc. or some combination thereof. The gate structure 510 is disposed on the metal 506 and has an insulator 504, 512 surrounding the gate structure 510. A dielectric 514 is disposed on the gate structure 510. The carrier deficient layer 508 is disposed on the dielectric 514. A source structure 524 and a drain structure 518 are in contact with the channel formed by the carrier deficient layer 508 and the electron injection layer 522. An insulator 520 is disposed between the source structure 524 and the drain structure 518. Also, an insulator 502 and another insulator 516 may optionally be disposed adjacent to the source structure 524 and the drain structure 518, respectively. The transistor 500 may be a BEOL or a FEOL transistor, in some specific embodiments.

FIG. 6 shows a cross-sectional view of a thin-film transistor 600 disposed on an insulator 602 having a channel with a carrier deficient layer 614 and an electron injection layer 618 in accordance with an embodiment of the present disclosure. The transistor 600 may be a FEOL transistor or a BEOL transistor. The transistor 600 may also be a thin-film transistor in some embodiments.

The transistor 600 includes the electron injection layer 618 disposed on the insulator 602 and the carrier deficient layer 614 disposed on the electron injection layer 618 thereby forming the channel. Insulators 604, 616 are disposed on opposite ends of the layers 614, 618. a source structure 606 is partially disposed on the carrier deficient layer 614 and as is the drain structure 614, which has a dielectric 608 positioned therebetween. The gate structure 610 is disposed on the dielectric 608. The transistor 600 may be a BEOL or a FEOL transistor, in some specific embodiments.

FIG. 7 shows a cross-sectional view of a ferroelectric field-effect transistor 700 disposed on a metal 706 having a channel with a carrier deficient layer 708 and an electron injection layer 722 in accordance with an embodiment of the present disclosure. The gate structure 710 is disposed on the metal 706 and has an insulator 704, 712 surrounding the gate structure 710. A ferroelectric material 714 is disposed on the gate structure 710. The carrier deficient layer 708 is disposed on the ferroelectric material 714. A source structure 724 and a drain structure 718 are in contact with the channel formed by the carrier deficient layer 708 and the electron injection layer 722. An insulator 720 is disposed between the source structure 724 and the drain structure 718. Also, an insulator 702 and another insulator 716 may optionally be disposed adjacent to the source structure 724 and the drain structure 718, respectively. The transistor 700 may be a BEOL or a FEOL transistors, in some specific embodiments.

FIG. 8 shows a cross-sectional view of a ferroelectric field-effect transistor 800 disposed on an insulator 802 having a channel with a carrier deficient layer 814 and an electron injection layer 818 in accordance with an embodiment of the present disclosure. The transistor 800 may be a FEOL transistor or a BEOL transistor. The transistor 800 may also be a thin-film transistor in some embodiments.

The transistor 800 includes the electron injection layer 818 disposed on the insulator 802 and the carrier deficient layer 814 disposed on the electron injection layer 818 thereby forming the channel. Insulators 804, 816 are disposed on opposite ends of the layers 814, 818. A source structure 806 is partially disposed on the carrier deficient layer 814 and as is the drain structure 814, which has a ferroelectric material 608 is positioned therebetween. The gate structure 610 is disposed on the dielectric 608. The transistor 800 may be a BEOL or a FEOL transistor, in some specific embodiments.

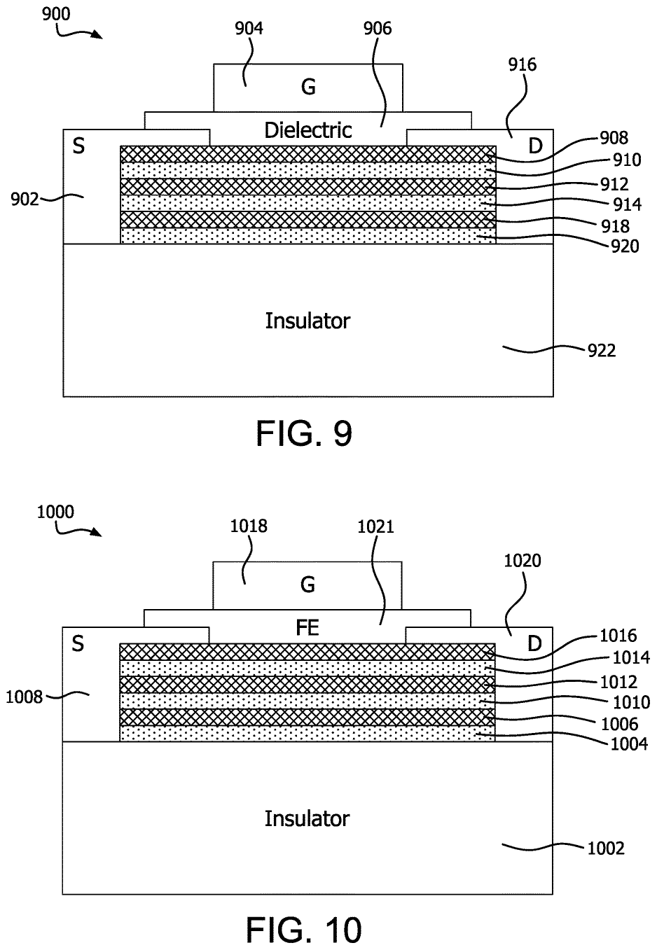

FIG. 9 shows a cross-sectional view of a thin-film transistor 900 having a channel with interleaved carrier deficient layers 908, 912, 918 and electron injection layers 910, 914, 920 in accordance with an embodiment of the present disclosure. The transistor 900 may be BEOL or FEOL transistors, in some specific embodiments. The transistor 900 of FIG. 9 may be similar to the transistor 200 of FIG. 2; however, the transistor 900 has the interleaved channel where there are interleaved carrier deficient layers 908, 912, 918 and electron injection layers 910, 914, 920.

The transistor 900 includes an insulator 922 where a source structure 902 and a drain structure 916 are partially disposed on. The interleaved channel where there are interleaved carrier deficient layers 908, 912, 918 and electron injection layers 910, 914, 920 are disposed on the insulator 922 and between the source structure 902 and the drain structure 916. A dielectric 906 is then disposed partially on the channel structure, the source structure 902, and the drain structure 916. A gate structure 904 is disposed on the dielectric layer 906. The transistor 900 may be a BEOL or a FEOL transistor, in some specific embodiments. In yet additional embodiments, the insulator 922 may be a metal with sufficient or optional insulation layers added as one of ordinary skill in the relevant art would know.

FIG. 10 shows a cross-sectional view of a ferroelectric field-effect transistor 1000 having a channel with interleaved carrier deficient layers 1016, 1012, 1006 and electron injection layers 1014, 1010, 1004 in accordance with an embodiment of the present disclosure. The transistor 1000 may be BEOL or FEOL transistors, in some specific embodiments. The transistor 1000 includes an insulator 1002 with a source structure 1008 and a drain structure 1020 disposed thereon. The channel is disposed between the source structure 1008 and the drain structure 1020 and includes carrier deficient layers 1016, 1012, 1006 interleaved with electron injection layers 1014, 1010, 1004. A ferroelectric layer 1020 is disposed on top of the channel structure, the source structure 1008, and the drain structure 1020. A gate structure 1018 is disposed on the ferroelectric layer 1021. The transistor 1000 may be a BEOL or a FEOL transistor, in some specific embodiments. In yet additional embodiments, the insulator 1002 may be a metal with sufficient or optional insulation layers added as one of ordinary skill in the relevant art would know.

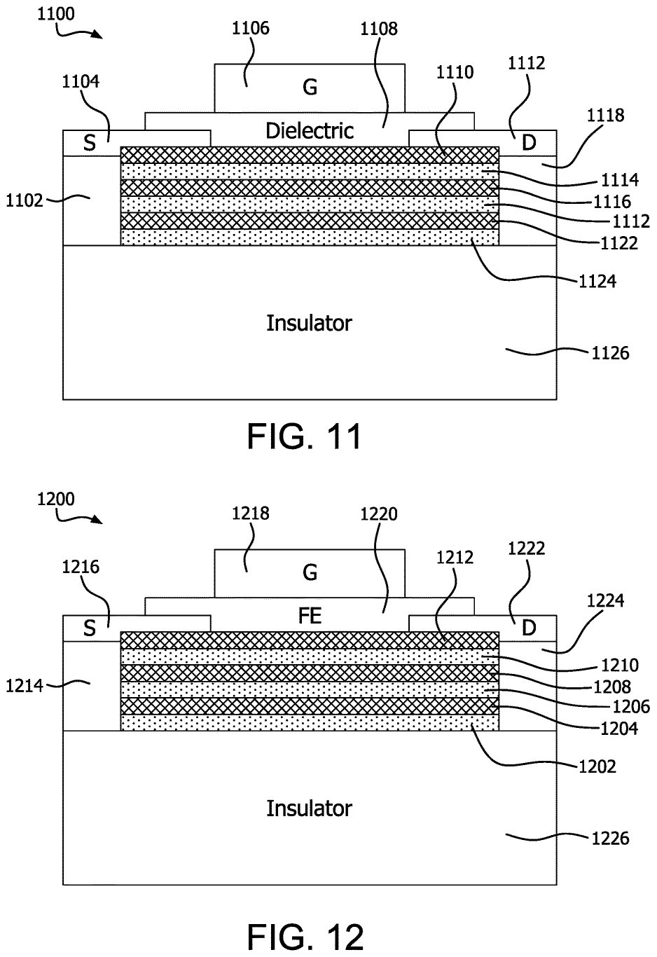

FIG. 11 shows a cross-sectional view of a thin-film transistor having 1100 a channel with interleaved carrier deficient layers 1110, 1116, 1122 and electron injection layers 1114, 1120, 1124 in accordance with an embodiment of the present disclosure. The transistor 1100 may be BEOL or FEOL transistors, in some specific embodiments. The transistor 1100 of FIG. 11 may be similar to the transistor 900 of FIG. 9; however, the transistor 1100 has insulation layers 1102, 1118.

The transistor 1100 includes an insulator 1126 and the insulators 1102, 1118 wherein a source structure 1104 and a drain structure 1112 are partially disposed on, respectively. The interleaved channel where there are interleaved carrier deficient layers 1110, 1116, 1122 and electron injection layers 1114, 1120, 1124 are disposed on the insulator 1126 and between the source structure 1104/insulator 1102 and the drain structure 1112/insulator 1118. A dielectric 118 is then disposed partially on the channel structure, the source structure 1104, and the drain structure 1112. A gate structure 1106 is disposed on the dielectric layer 1108. The transistor 1100 may be a BEOL or a FEOL transistor, in some specific embodiments. In yet additional embodiments, the insulator 1126 may be a metal with sufficient or optional insulation layers added as one of ordinary skill in the relevant art would know.

FIG. 12 shows a cross-sectional view of a ferroelectric field-effect transistor 1200 having a channel with interleaved carrier deficient layers 1212, 1208, 1204 and electron injection layers 1210, 1206, 1202 in accordance with an embodiment of the present disclosure. The transistor 1200 may be BEOL or FEOL transistors, in some specific embodiments. The transistor 1200 includes an insulator 1226 with a source structure 1216 and a drain structure 1222 disposed thereon. The channel is disposed between the source structure 1216/insulation 1214 and the drain structure 1222/insulation 1224 and includes carrier deficient layers 1212, 1208, 1204 interleaved with electron injection layers 1210, 1206, 1202. A ferroelectric layer 1220 is disposed on top of the channel structure, the source structure 1216, and the drain structure 1222. A gate structure 10121818 is disposed on the ferroelectric layer 1218. The transistor 1200 may be a BEOL or a FEOL transistor, in some specific embodiments. In yet additional embodiments, the insulator 1226 may be a metal with sufficient or optional insulation layers added as one of ordinary skill in the relevant art would know.

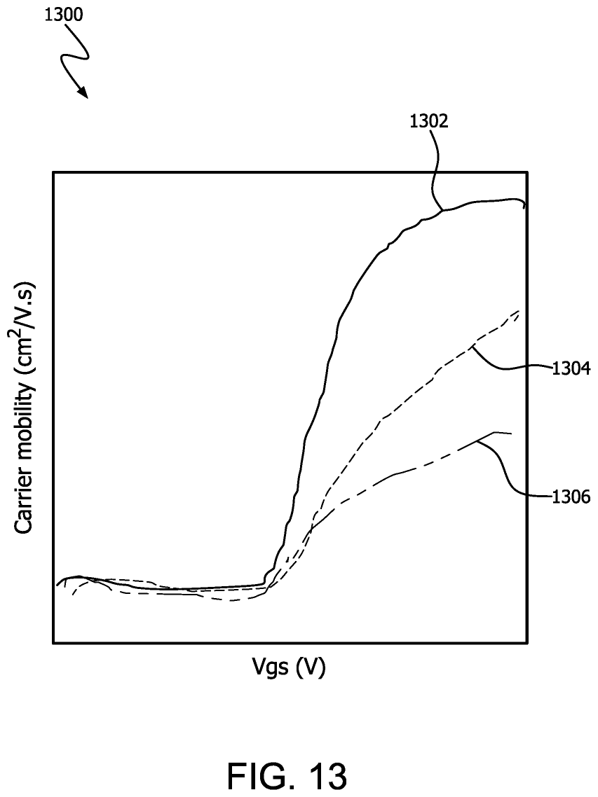

FIG. 13 shows a graphic 1300 illustrating prophetic results expected from having a channel layer with various types of materials in accordance with an embodiment of the present disclosure. The graphic 1300 shows the Vgs vs. carrier mobility for different material configurations as described herein. The plot 1306 shows a plot with the channel being made of only carrier deficient channel material. The plot 1302 shows the expected plot from a device with a multi-layer channel material, e.g., interleaved material as described above, while the plot 1304 shows the expected result from a device with only carrier injection channel material. As can be seen, the different layers can be used to control the characteristics of a transistor.

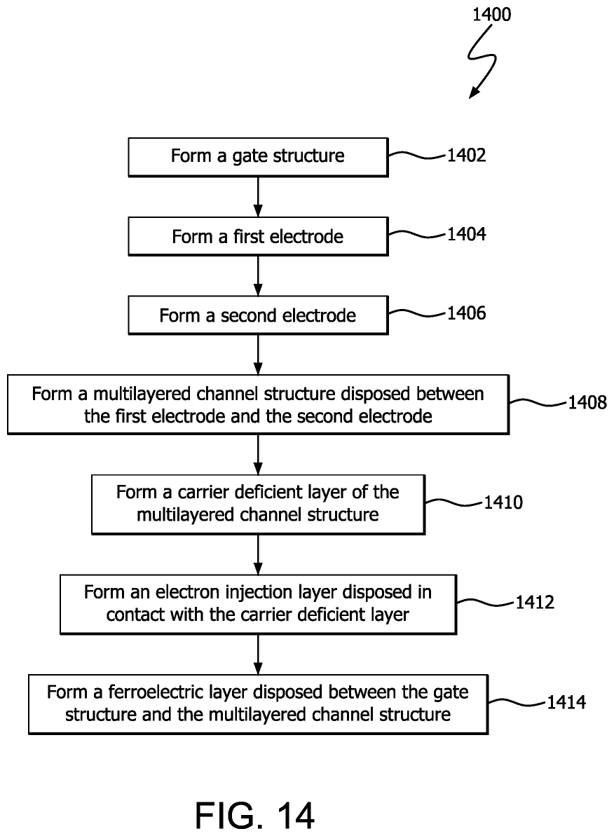

FIG. 14 is a flowchart diagram of example method 1400 for forming a device. The method 1400 may include forming a gate structure (block 1402). The method 1400 may also include forming a first electrode (block 1404) and forming a second electrode (block 1406). The method 1400 may the act 1408 of forming a multilayered channel structure disposed between the first electrode and the second electrode. The method 1400 may include act 1410 of forming a carrier deficient layer of the multilayered channel structure and act 1412 of forming an electron injection layer disposed in contact with the carrier deficient layer (block 1408). The method 1400 may include the act of 1414, which forms a ferroelectric layer disposed between the gate structure and the multilayered channel structure

Although FIG. 14 shows example blocks of a method 1400, in some implementations, the method 1400 may include additional blocks, fewer blocks, different blocks, or differently arranged blocks than those depicted in FIG. 14. Additionally, or alternatively, two or more of the blocks of process 800 may be performed in parallel.

Various alternatives and modifications can be devised by those skilled in the art without departing from the disclosure. Accordingly, the present disclosure is intended to embrace all such alternatives, modifications and variances. Additionally, while several embodiments of the present disclosure have been shown in the drawings and/or discussed herein, it is not intended that the disclosure be limited thereto, as it is intended that the disclosure be as broad in scope as the art will allow and that the specification be read likewise. Therefore, the above description should not be construed as limiting, but merely as exemplifications of particular embodiments. And, those skilled in the art will envision other modifications within the scope and spirit of the claims appended hereto. Other elements, steps, methods and techniques that are insubstantially different from those described above and/or in the appended claims are also intended to be within the scope of the disclosure.

For example, the channels described herein may include additional layers, such as n-type layers including: ITO, IGZO, IZO, AZO, a-Si, ZnO, a-Ge, polysilicon or poly-Si, poly-Ge, or poly-III-V like InAs, etc. and/or p-type layers such as: a-Si, ZnO, a-Ge, polysilicon, poly germanium, poly-III-V like InAs, CuO, SnO, etc. The channel length may be any suitable length known to one of ordinary skill in the relevant art including, but not limited to, from 5 nm to 100 nm. The layers may be formed using atomic layer deposition and may be any suitable thickness known to one of ordinary skill in the relevant art including, but not limited to, from 2 nm to 10 nm. In some embodiments there are an odd number of carrier deficient layers (e.g., 1, 3, 5, 7, 9, etc.) and an even number of electron injection layers (2, 4, 6, 8, 10, etc). In yet other embodiments, there are an even number of carrier deficient layers (2, 4, 6, 8, 10, etc) and an odd number of electron injection layers (e.g., 1, 3, 5, 7, 9, etc.). In yet other embodiments, there are an even number of carrier deficient layers (2, 4, 6, 8, 10, etc) and an even number of electron injection layers (2, 4, 6, 8, 10, etc).

The embodiments shown in the drawings are presented only to demonstrate certain examples of the disclosure. And, the drawings described are only illustrative and are non-limiting. In the drawings, for illustrative purposes, the size of some of the elements may be exaggerated and not drawn to a particular scale. Additionally, elements shown within the drawings that have the same numbers may be identical elements or may be similar elements, depending on the context.

Where the term “comprising” is used in the present description and claims, it does not exclude other elements or steps. Where an indefinite or definite article is used when referring to a singular noun, e.g., “a,” “an,” or “the,” this includes a plural of that noun unless something otherwise is specifically stated. Hence, the term “comprising” should not be interpreted as being restricted to the items listed thereafter; it does not exclude other elements or steps, and so the scope of the expression “a device comprising items A and B” should not be limited to devices consisting only of components A and B. This expression signifies that, with respect to the present disclosure, the only relevant components of the device are A and B.

Furthermore, the terms “first,” “second,” “third,” and the like, whether used in the description or in the claims, are provided for distinguishing between similar elements and not necessarily for describing a sequential or chronological order. It is to be understood that the terms so used are interchangeable under appropriate circumstances (unless clearly disclosed otherwise) and that the embodiments of the disclosure described herein are capable of operation in other sequences and/or arrangements than are described or illustrated herein.

Each of the characteristics and examples described herein, and combinations thereof, may be said to be encompassed by the present disclosure. Numerous variations and configurations will be apparent in light of this disclosure and the following examples:

Example 1: A semiconductor device, comprising: a gate structure; a first electrode; a second electrode; and a multilayered channel structure electrically coupled to the first electrode and the second electrode, the multilayered channel structure comprising: a carrier deficient layer; and an electron injection layer disposed on the carrier deficient layer.

Example 2: The device according to Example 1, further comprising a dielectric layer disposed between the gate structure and the multilayered channel structure.

Example 3: The device according to Example 2, wherein the dielectric layer is formed from a ferroelectric material.

Example 4: The device according to Example 1, wherein the multilayered channel structure comprises: a plurality of carrier deficient layers including the carrier deficient layer; and a plurality of electron injection layers including the electron injection layer, wherein the plurality of carrier deficient layers and the plurality of electron injection layers are interleaved together to thereby form an interleaved multilayered channel structure.

Example 5: The device according to Example 4, further comprising a ferroelectric layer disposed between the gate structure and the interleaved multilayered channel structure.

Example 6: The device according to Example 1, further comprising an insulator.

Example 7: The device according to Example 6, wherein the multilayered channel structure is disposed on the insulator, wherein a first side insulator is disposed on a first side of the multilayered channel structure and a second side insulator is disposed on a second side of the multilayered channel structure.

Example 8: The device according to Example 7, wherein the first side insulator is in contact with the insulator and the second side insulator is in contact with the insulator.

Example 9: The device according to Example 6, wherein the gate structure is disposed on the insulator.

Example 10: The device according to Example 9, wherein the gate structure forms a trapezoidal cross-sectional shape.

Example 11: The device according to Example 9, wherein a dielectric layer is disposed on the gate structure and the insulator.

Example 12: The device according to Example 11, wherein the multilayered channel structure is disposed on the dielectric layer.

Example 13: The device according to Example 12, wherein the first electrode and the second electrode are in electrical communication with each other through the multilayered channel structure.

Example 14: The device according to Example 6, wherein the multilayered channel structure is disposed on the insulator.

Example 15: The device according to Example 14, wherein a dielectric layer is disposed on the multilayered channel structure.

Example 16: The device according to Example 15, wherein the gate structure is disposed on the dielectric layer.

Example 17: The device according to Example 15, wherein the dielectric layer is made of a ferroelectric material.

Example 18: The device according to Example 15, wherein the first electrode is in electrical communication with the multilayered channel structure.

Example 19: The device according to Example 15, wherein the first electrode is in physical contact with the multilayered channel structure.

Example 20: The device according to Example 19, wherein the first electrode is in physical contact with the dielectric layer.

Example 21: The device according to Examples 19 or 20, wherein the first electrode is in physical contact with the insulator.

Example 22: The device according to Examples 19 or 20, further comprising another insulator disposed adjacent to the first electrode at an opposite side to the multilayered channel structure.

Example 23: The device according to any one of Examples 1 to 5, further comprising a metal, wherein the gate structure is disposed on the metal.

Example 24: The device according to Example 23, further comprising a dielectric layer disposed on the gate structure.

Example 25: The device according to Example 24, wherein the first electrode is disposed on the multilayered channel structure and the dielectric layer and the second electrode is disposed on the multilayered channel structure and the dielectric layer.

Example 26: The device according to Example 25, further comprising an interposed insulator disposed between the first electrode and the second electrode.

Example 27: The device according to Example 24, wherein the multilayered channel structure is disposed on the dielectric layer.

Example 28: The device according to Example 23, further comprising a ferroelectric material disposed on the gate structure.

Example 29: The device according to Example 28, wherein the multilayered channel structure is disposed on the ferroelectric material.

Example 30: The device according to any one of Examples 1 to 29, further comprising a first insulator disposed adjacent to the gate structure on a first side and a second insulator disposed adjacent to the gate structure on a second side.

Example 31: The device according to any one of Examples 1 to 30, wherein the first electrode is a source structure.

Example 32: The device according to any one of Examples 1 to 31, wherein the second electrode is a drain structure.

Example 33: The device according to any one of Examples 1 to 32, wherein the carrier deficient layer is an indium(III) oxide layer with an added dopant with a high bond-dissociation energy.

Example 34: The device according to Example 33, wherein the added dopant is selected from the group consisting of tungsten(VI) oxide, silicon dioxide, and antimony tetroxide.

Example 35: The device according to any one of Examples 1 to 34, wherein the electron injection layer is pure indium(III) oxide.

Example 36: The device according to any one of Examples 1 to 35, wherein the electron injection layer is indium(III) oxide annealed in air.

Example 37: The device according to any one of Examples 1 to 36, wherein the electron injection layer is indium(III) oxide annealed with an added dopant with a low bond-dissociation energy.

Example 38: The device according to Example 37, wherein the added dopant is a titanium dioxide.

Example 39: The device according to any one of Examples 1 to 38, wherein the device is a thin-film transistor.

Example 40: The device according to any one of Examples 1 to 39, wherein the device is disposed on a back-end of a line portion of an integrated circuit.

Example 41: The device according to any one of Examples 1 to 39, wherein the device is disposed on a front-end of a line portion of an integrated circuit.

Example 42: The device according to any one of Examples 1 to 41, wherein the multilayered channel structure is less than 10 nanometers in thickness.

Example 43: The device according to any one of Examples 1 to 42, wherein the carrier deficient layer has a first thickness and the electron injection layer has a second thickness, wherein a ratio between the first thickness and the second thickness is predetermined.

Example 44: An integrated circuit system, comprising: at least one integrated circuit having a plurality of devices, wherein at least one device of the plurality of devices is a device according to any of Examples 1-43.

Example 45: The device according to any one of Examples 2, 11-12, 15-16, 20, 24-25, or 27, wherein the dielectric layer is a ferroelectric layer.

Example 46: A method of making an integrated circuit, the method comprising: forming a gate structure; forming a first electrode; forming a second electrode; forming a multilayered channel structure disposed between the first electrode and the second electrode; forming a carrier deficient layer of the multilayered channel structure; and forming an electron injection layer disposed in contact with the carrier deficient layer.

Example 47: The method according to Example 46, wherein the carrier deficient layer is an indium(III) oxide layer, wherein the method further comprises adding a dopant with a high bond-dissociation energy to the indium(III) oxide layer.

Example 48: The method according to Example 47, wherein the dopant is selected from the group consisting of tungsten(VI) oxide, silicon dioxide, and antimony tetroxide.

Example 49: The method according to Example 46, wherein the electron injection layer is pure indium(III) oxide.

Example 50: The method according to Example 46, wherein the electron injection layer is indium(III) oxide, wherein the method further comprises annealing the electron injection layer in air.

Example 51: The method according to Example 46, wherein the electron injection layer is indium(III) oxide, wherein the method further comprises annealing the electron injection layer with an added dopant with a low bond-dissociation energy.

Example 52: The method according to Example 51, wherein the added dopant is a titanium dioxide.

Example 53: The method according to Example 46, wherein the method forms a thin-film transistor.

Example 54: The method according to Example 46, further comprising forming a dielectric layer disposed between the gate structure and the multilayered channel structure.

Example 55: The method according to Example 54, further comprising forming the dielectric layer from a ferroelectric material.

Example 56: The method according to Example 46, wherein each forming act is performed on a back-end of a line portion of an integrated circuit.

Example 57: The method according to Example 46, further comprising forming less than 10 nanometers of thickness of the multilayered channel structure.

Example 58: The method according to Example 46, wherein the carrier deficient layer has a first thickness and the electron injection layer has a second thickness, wherein the method further comprises predetermining a ratio between the first thickness and the second thickness.

Example 59: The method according to Example 46, further comprising: forming a plurality of carrier deficient layers including the carrier deficient layer; forming a plurality of electron injection layers including the electron injection layer; and interleaving the plurality of carrier deficient layers and the plurality of electron injection layers thereby forming an interleaved multilayered channel structure.

Example 60: The method according to Example 59, forming a ferroelectric layer disposed between the gate structure and the interleaved multilayered channel structure.

Example 61: The method according to Example 46, further comprising forming an insulator.

Example 62: The method according to Example 61, further comprising forming the gate structure on the insulator.

Example 63: The method according to Example 62, further comprising forming a trapezoidal cross-sectional shape of the gate structure.

Example 64: The method according to Example 62, further comprising forming a dielectric layer on the gate structure and the insulator.

Example 65: The method according to Example 64, further comprising forming the multilayered channel structure on the dielectric layer.

Example 66: The method according to Example 65, further comprising communicating electrically between the first electrode and the second electrode through the multilayered channel structure.

Example 67: The method according to Example 61, further comprising forming the multilayered channel structure on the insulator.

Example 68: The method according to Example 67, further comprising forming a dielectric layer on the insulator.

Example 69: The method according to Example 68, further comprising forming the gate structure on the insulator.

Example 70: The method according to Example 68, further comprising forming the dielectric layer from a ferroelectric material.

Example 71: The method according to Example 68, further comprising electrically communicating the first electrode with the multilayered channel structure.

Example 72: The method according to Example 68, wherein the first electrode is in physical contact with the multilayered channel structure.

Example 73: The method according to Example 68, wherein the first electrode is in physical contact with the dielectric layer.

1. A semiconductor device, comprising:
a gate structure;
a first electrode;
a second electrode; and
a multilayered channel structure electrically coupled to the first electrode and the second electrode, the multilayered channel structure comprising:
a carrier deficient layer; and
an electron injection layer disposed on the carrier deficient layer.

2. The device according to claim 1, further comprising a dielectric layer disposed between the gate structure and the multilayered channel structure.

3. The device according to claim 2, wherein the dielectric layer is formed from a ferroelectric material.

4. The device according to claim 1, wherein the multilayered channel structure comprises:
a plurality of carrier deficient layers including the carrier deficient layer; and
a plurality of electron injection layers including the electron injection layer, wherein the plurality of carrier deficient layers and the plurality of electron injection layers are interleaved together to thereby form an interleaved multilayered channel structure.

5. The device according to claim 4, further comprising a ferroelectric layer disposed between the gate structure and the interleaved multilayered channel structure.

6. The device according to claim 1, further comprising an insulator.

7. The device according to claim 6, wherein the multilayered channel structure is disposed on the insulator, wherein a first side insulator is disposed on a first side of the multilayered channel structure and a second side insulator is disposed on a second side of the multilayered channel structure.

8. The device according to claim 7, wherein the first side insulator is in contact with the insulator and the second side insulator is in contact with the insulator.

9. The device according to claim 6, wherein the gate structure is disposed on the insulator.

10. The device according to claim 9, wherein the gate structure forms a trapezoidal cross-sectional shape.

11. The device according to claim 9, wherein a dielectric layer is disposed on the gate structure and the insulator.

12. The device according to claim 11, wherein the multilayered channel structure is disposed on the dielectric layer.

13. The device according to claim 12, wherein the first electrode and the second electrode are in electrical communication with each other through the multilayered channel structure.

14. The device according to claim 6, wherein the multilayered channel structure is disposed on the insulator.

15. The device according to claim 14, wherein a dielectric layer is disposed on the multilayered channel structure.

16. The device according to claim 15, wherein the gate structure is disposed on the dielectric layer.

17. The device according to claim 15, wherein the dielectric layer is made of a ferroelectric material.

18. The device according to claim 15, wherein the first electrode is in electrical communication with the multilayered channel structure.

19. The device according to claim 15, wherein the first electrode is in physical contact with the multilayered channel structure.

20. The device according to claim 19, wherein the first electrode is in physical contact with the dielectric layer.

21. The device according to claim 19, wherein the first electrode is in physical contact with the insulator.

22. The device according to claim 19, further comprising another insulator disposed adjacent to the first electrode at an opposite side to the multilayered channel structure.

23. The device according to claim 1, further comprising a metal, wherein the gate structure is disposed on the metal.

24. The device according to claim 23, further comprising a dielectric layer disposed on the gate structure.

25. The device according to claim 24, wherein the first electrode is disposed on the multilayered channel structure and the dielectric layer and the second electrode is disposed on the multilayered channel structure and the dielectric layer.

26. The device according to claim 25, further comprising an interposed insulator disposed between the first electrode and the second electrode.

27. The device according to claim 24, wherein the multilayered channel structure is disposed on the dielectric layer.

28. The device according to claim 23, further comprising a ferroelectric material disposed on the gate structure.

29. The device according to claim 28, wherein the multilayered channel structure is disposed on the ferroelectric material.
